(19) United States
(12) Patent Application Publication
(10) Pub. No.: US 2009/0091009 A1
(43) Pub. Date: Apr. 9, 2009

(54) STACKABLE INTEGRATED CIRCUIT PACKAGE

(76) Inventors: David J. Corisis, Nampa, ID (US); Chin Hui Chong, Singapore (SG); Choon Kuan Lee, Singapore (SG)

Correspondence Address: PERKINS COIE LLP;PATENT-SEA, PO BOX 1247, SEATTLE, WA, 98111-1247, US

(21) Appl. No.: 11/866,788

(22) Filed: Oct. 3, 2007

(51) Int. Cl. H01L 23/495; H01L 21/00

(52) U.S. Cl. 257/670; 438/109; 257/E23.031

(57) ABSTRACT

A packaged integrated circuit device is disclosed which includes a leadframe comprising a die paddle and a plurality of lead fingers, a plurality of integrated circuit die positioned above the paddle in a stacked arrangement, a plurality of conductive structures for coupling each of the plurality of die to the lead fingers and a body of encapsulant material positioned around the plurality of die and the plurality of conductive structures, wherein the plurality of lead fingers are folded such that a portion of the lead fingers is positioned above the top surface of the body of encapsulant material. A method is also disclosed which includes attaching a first die to a paddle of a leadframe comprising a plurality of lead fingers, positioning at least one additional die above the first die, the first and the at least one additional die being electrically coupled to the plurality of lead fingers, forming a body of encapsulant material around the first die and the at least one additional die and folding the plurality of lead fingers such that a portion of the lead fingers is positioned above a top surface of the body of encapsulant material.

### BACKGROUND

1. Technical Field

This present subject matter is generally directed to the field of packaging integrated circuit devices, and, more particularly, to a stackable integrated circuit package.

2. Description of the Related Art

Integrated circuit technology uses electrical devices, e.g., transistors, resistors, capacitors, etc., to formulate vast arrays of functional circuits. The complexity of these circuits requires the use of an ever-increasing number of linked electrical devices so that the circuit may perform its intended function. As the number of transistors increases, the integrated circuitry dimensions shrink. One challenge in the semiconductor industry is to develop improved methods for electrically connecting and packaging circuit devices which are fabricated on the same and/or on different wafers or chips. In general, it is desirable in the semiconductor industry to construct transistors which occupy less surface area on the silicon chip/die.

In the manufacture of semiconductor device assemblies, a single semiconductor die is most commonly incorporated into each sealed package. Many different package styles are used, including dual inline packages (DIP), zig-zag inline packages (ZIP), small outline J-bends (SOJ), thin small outline packages (TSOP), plastic leaded chip carriers (PLCC), small outline integrated circuits (SOIC), plastic quad flat packs (PQFP) and interdigitated leadframe (IDF). Some semiconductor device assemblies are connected to a substrate, such as a circuit board, prior to encapsulation. In some applications, integrated circuit die are packaged in a stacked configuration in an effort to reduce the plot space occupied by the integrated circuit product. Manufacturers are under constant pressure to reduce the size of the packaged integrated circuit device and to increase the packaging density in packaging integrated circuit devices.

### BRIEF DESCRIPTION OF THE DRAWINGS

The present subject matter may be understood by reference to the following description taken in conjunction with the accompanying drawings, in which like reference numerals identify like elements, and in which:

FIGS. 1 and 2 are cross-sectional views of illustrative embodiments of the stackable integrated circuit package disclosed herein;

FIG. 3 is a cross-sectional view depicting an illustrative example wherein a plurality of the stackable integrated circuit packages disclosed herein are operatively coupled to a printed circuit board;

FIG. 4 is a plan view of one illustrative embodiment of a stackable integrated circuit package disclosed herein; and

FIGS. 5A-4G depict one illustrative process flow that may be employed to form the stackable integrated circuit packages described herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

Although various regions and structures shown in the drawings are depicted as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the subject matter disclosed herein.

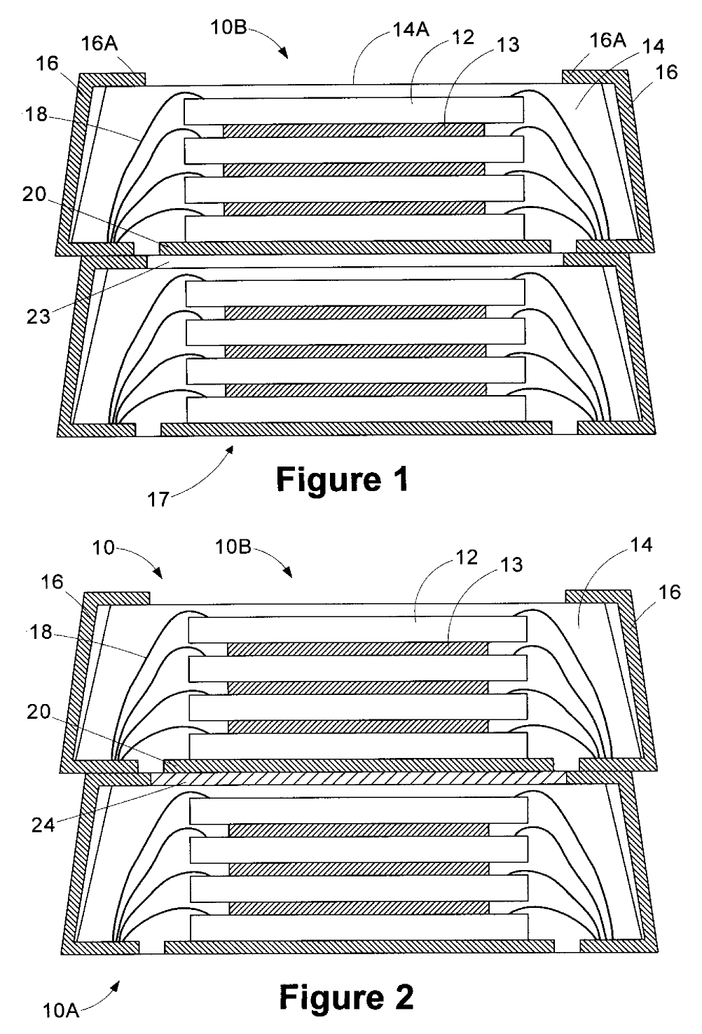

As shown in FIGS. 1 and 2, in one illustrative embodiment, two illustrative stackable packages 10A, 10B are stacked together. Each of the packages 10A, 10B are comprised of a plurality of integrated circuit die 12 that are coupled to one another by an adhesive or epoxy material 13. The die 12 are positioned above a paddle 20 of a traditional leadframe that is comprised of a plurality of leads or lead fingers 16. The integrated circuit die 12 are electrically coupled to the lead fingers 16 by illustrative wire bonds 18. An encapsulant material 14, e.g., mold compound, is formed around the various components described above. As can be observed in the drawings, the lead fingers 16 are bent or folded such that a portion 16A of the lead finger 16 is positioned above a top surface 14A of the encapsulant material 14, e.g., mold compound.

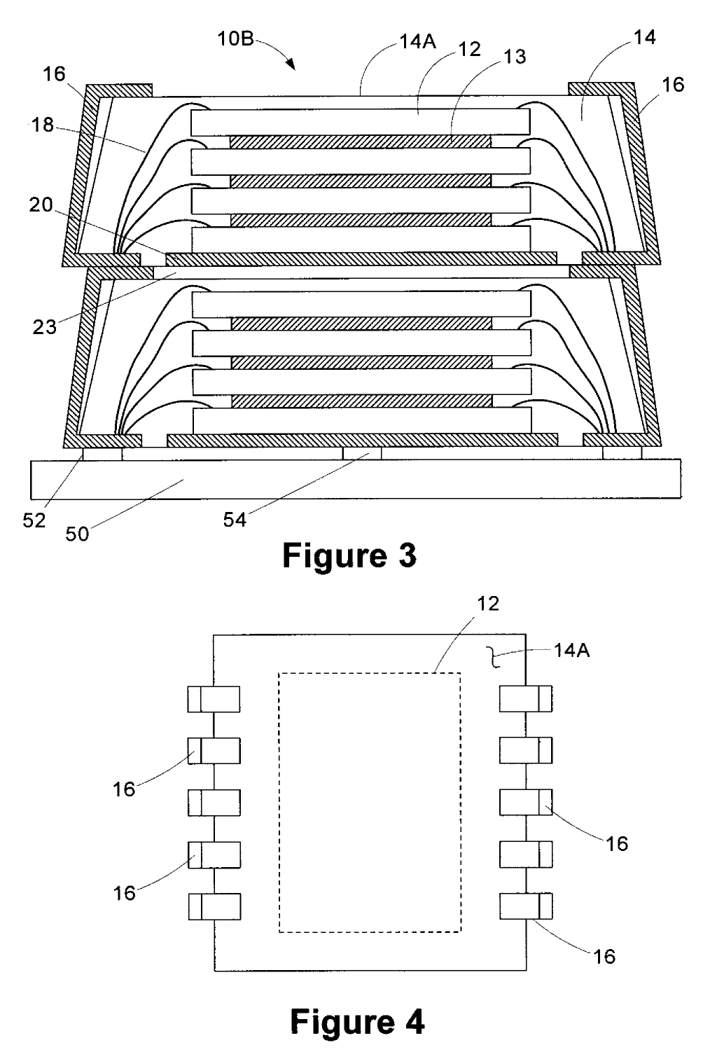

It should also be noted that each of the packages 10A, 10B has a substantially planar bottom surface 17. The packages 10A, 10B are electrically coupled to one another through use of an electrically conductive adhesive or paste (not shown) positioned between the engaging portions of the lead fingers 16 on each package 10A, 10B. In practice, as shown in FIG. 3, the bottom surface of such a package, e.g., package 10A, may be electrically coupled to another structure, such as a printed circuit board 50, using a variety of known techniques. For example, conductive paste or adhesive (not shown) may be applied to pads 52 on the printed circuit board 50. If desired, a contact 54 may be provided to the paddle 20 as well.

It should also be noted that the depiction of four illustrative die 12 in each of the packages 10A, 10B is provided by way of example only. As will be recognized by those skilled in the art after a complete reading of the present application, the subject matter disclosed herein may be employed in packaging any number of such die within one of the packages 10A or 10B. Moreover, the number of die 12 within each package 10A, 10B need not be the same. Additionally, the die 12 within each package, e.g., package 10A, may be of the same or different physical sizes. Lastly, although FIGS. 1 and 2 depict two illustrative stacked packages 10A, 10B, the present invention may be employed to stack any desired number of such packages together, e.g., 3-5 such packages. Thus, the subject matter disclosed herein has broad application and should not be considered as limited to the particular details disclosed herein.

In the embodiment shown in FIG. 1, an air gap 23 is provided between the packages 10A, 10B. If desired, as shown in FIG. 2, a thermally conductive material 24 may be formed or positioned so as to fill the air gap 23, thereby providing increased heat transfer capabilities for the stacked packages 10A, 10B. In one illustrative embodiment, the thermally conductive material 24 may be comprised of a thermally conductive paste or tape, and it may have a thickness of approximately 100-200 μm. Such thermally conductive materials are well known to those skilled in the art.

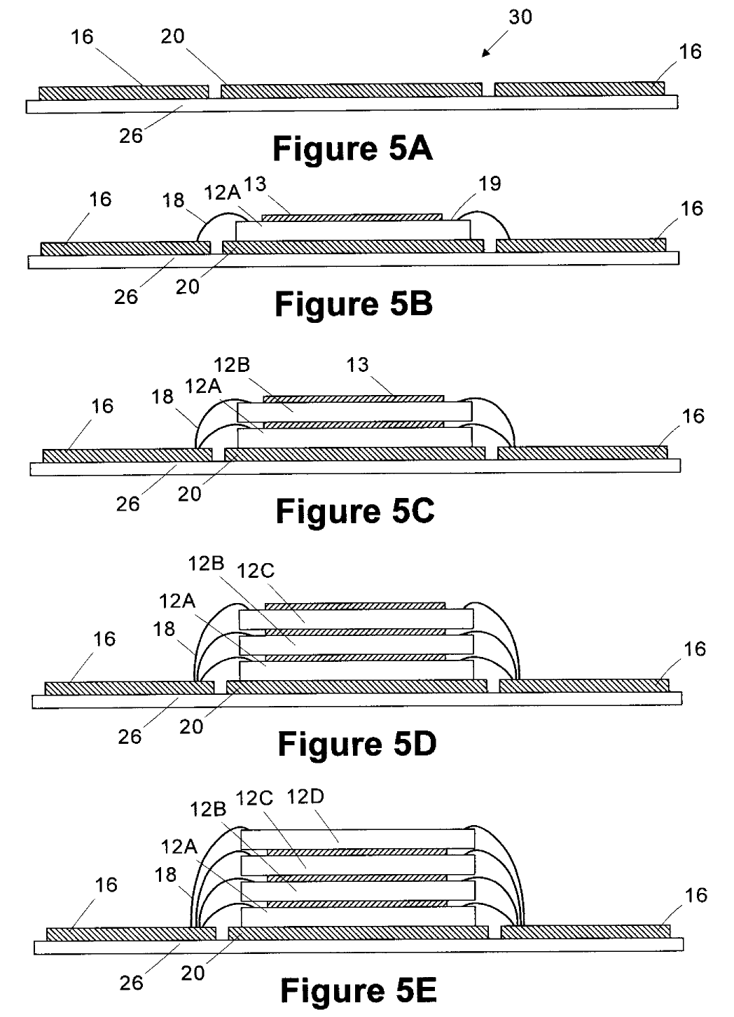

FIG. 4 is a plan view of the top of the package 10B in FIG. 1. As shown therein, five illustrative lead fingers 16 extend along only the sides of the integrated circuit die 12. In practice, an actual product may have a large number of such lead fingers 16, however, for purposes of clarity, only ten such lead fingers 16 are shown in FIG. 4. Of course, in other applications, the lead fingers 16 may extend around the entire perimeter of the package 10B or only along the ends of the package 10B. Thus, the illustrative arrangements depicted herein should not be considered to be a limitation of the present subject matter.

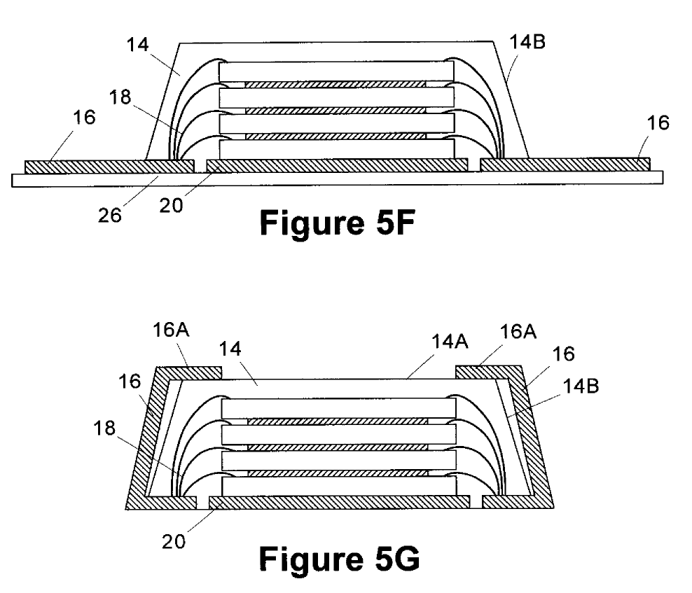

FIGS. 5A-5G depict one illustrative process flow for forming a stackable package as described herein. As shown in FIG. 5A, a leadframe 30 is positioned above a sacrificial support structure 26. The leadframe 30 comprises an illustrative die paddle 20 and a plurality of lead fingers 16. It should be noted that the leadframe 30 depicted in the figures is schematically depicted for purposes of explanation, the drawings are not to scale. In an actual device, the relative sizes of the various components and structures depicted herein may be different than what is depicted herein. The leadframe 30 may be of traditional construction and it may be made from a variety of conductive materials, e.g., copper, Alloy 42, etc. The leadframe 30 may be initially secured to the sacrificial structure 26 by using an adhesive material (not shown) or employing other similar techniques.

As shown in FIG. 5B, a first die 12A is secured above the paddle 20 by an adhesive material (not shown). If desired, the die 12A may be electrically coupled to the paddle 20 via contact pads (not shown) on the bottom surface 15 of the die 12A. The electrical connection may be established by applying a conductive paste or other similar materials (not shown). Additionally, in some applications, the die 12A may be coupled to the paddle 20 in such a manner as to promote heat transfer between the die 12A and the paddle 20. For example, an adhesive designed to provide enhanced heat transfer capabilities may be provided in an effort to increase the effectiveness of the heat transfer between the die 12A and the paddle 20. The die 12A is also electrically coupled to one or more of the lead fingers 16. In one illustrative embodiment, wire bonds 16 may be employed for this purpose. The wire bond 16 may be conductively coupled to bond pads (not shown) on the die 12A and to the lead fingers 16 using known techniques. Thereafter, a layer of adhesive material 13 is applied to the upper surface 19 of the die 12A to attach another die 12B, as shown in FIG. 5C. The process is essentially repeated to attach illustrative dies 12C (FIG. 5D) and 12D (FIG. 5E).

Next, as shown in FIG. 5F, the encapsulant material 14 is formed around the structure depicted in FIG. 5E. The encapsulant material 14 may be formed using a variety of known molding techniques, e.g., transfer molding, and materials, e.g., mold compound. The release angle of the side surfaces 14B may vary depending upon the particular application. In one illustrative embodiment, the release angle may be approximately 8-20 degrees.

Next, as shown in FIG. 5G, the lead fingers 18 are bent or folded such that portion 16A of the lead finger 16 is positioned above a portion of the top surface 14A of the encapsulant material 14. Note that the angle of the folded lead finger 16 need not match the angle of the side surface 14B of the encapsulant material 14.

The device depicted in FIG. 5G may thereafter be subjected to a variety of different tests to confirm its capabilities and/or ability to perform its intended function. In fact, if desired, such testing may be performed at various stages during the manufacture of the device. Ultimately, the objective is to only stack packages, e.g., packages 10A, 10B, that are “known good,” i.e., packages that have passed a desired set of electrical and/or mechanical integrity tests.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A packaged integrated circuit device, comprising:
a leadframe comprising a die paddle and a plurality of lead fingers;
a plurality of integrated circuit die positioned above the paddle in a stacked arrangement;
a plurality of conductive structures for coupling each of the plurality of die to the lead fingers; and
a body of encapsulant material positioned around the plurality of die and the plurality of conductive structures, the body of encapsulant material having a top surface, wherein the plurality of lead fingers are folded such that a portion of the lead fingers is positioned above the top surface of the body of encapsulant material.

2. The device of claim 1, wherein the die paddle, the body of encapsulant material and the lead fingers define a substantially planar bottom surface.

3. The device of claim 2, wherein the plurality of conductive structures comprises a plurality of wire bonds.

4. The device of claim 3, wherein the plurality of lead fingers extend only along two opposed sides of the packaged integrated circuit device.

5. The device of claim 2, wherein a first of the plurality of die is coupled to the die paddle with an electrically conductive material.

6. The device of claim 2, wherein the plurality of integrated circuit die are coupled to one another by adhesive or epoxy material.

7. A stacked assembly, comprising:
a first packaged integrated circuit device and a second packaged integrated circuit device that is stacked above the first packaged integrated circuit device, each of the first and second packaged integrated circuit devices comprising:
a leadframe comprising a die paddle and a plurality of lead fingers;
a plurality of integrated circuit die positioned above the paddle in a stacked arrangement;
a plurality of conductive structures for coupling each of the plurality of die to the lead fingers; and
a body of encapsulant material positioned around the plurality of die and the plurality of conductive structures, the body of encapsulant material having a top surface, wherein the plurality of lead fingers are folded such that a portion of the lead fingers is positioned above the top surface of the body of encapsulant material.

8. The device of claim 7, wherein the lead fingers of the first and second packaged integrated circuit devices are electrically coupled to one another.

9. The device of claim 7, wherein a bottom surface of the lead fingers on the second packaged integrated circuit device is conductively coupled to a top surface of the portions of the lead fingers on the first packaged integrated circuit device that are positioned above the top surface of the body of encapsulant material.

10. The device of claim 7, further comprising a printed circuit board that is electrically coupled to the lead fingers of the first packaged integrated circuit device.

11. The device of claim 10, wherein the printed circuit board is electrically coupled to the die paddle of the first packaged integrated circuit device.

12. The device of claim 7, further comprising a heat transfer material positioned below the die paddle of the second packaged integrated circuit device and a top surface of an uppermost of the plurality of die in the first integrated circuit package.

13. The device of claim 7, wherein the die paddle, the body of encapsulant material and the lead fingers define a substantially planar bottom surface.

14. The device of claim 13, wherein the plurality of conductive structures comprises a plurality of wire bonds.

15. The device of claim 7, wherein the plurality of lead fingers extend only along two opposed sides of the packaged integrated circuit device.

16. The device of claim 13, wherein a first of the plurality of die is coupled to the die paddle with an electrically conductive material.

17. The device of claim 13, wherein the plurality of integrated circuit die are coupled to one another by adhesive or epoxy material.

18. A method, comprising:
attaching a first die to a paddle of a leadframe comprising a plurality of lead fingers;
positioning at least one additional die above the first die, the first and the at least one additional die being electrically coupled to the plurality of lead fingers;
forming a body of encapsulant material around the first die and the at least one additional die; and
folding the plurality of lead fingers such that a portion of the lead fingers is positioned above a top surface of the body of encapsulant material.

19. The method of claim 18, wherein attaching the first die to the paddle comprises attaching the first die to the paddle with an electrically conductive material.

20. The method of claim 18, wherein the first die and the at least one additional die are electrically coupled to the lead fingers by a plurality of wire bonds.

21. The method of claim 18, wherein the lead fingers are positioned only along opposite sides of the die paddle.

22. The method of claim 20, wherein the first die is electrically coupled to the lead fingers prior to positioning the at least one additional die above the first die.

23. The method of claim 18, wherein the die paddle, the body of encapsulant material and the lead fingers define a substantially planar bottom surface.
